(19) United States
(12) Patent Application Publication
(10) Pub. No.: US 2014/0147964 A1
(43) Pub. Date: May 29, 2014

(54) Shadow Mask, Evaporation Device and Method for Manufacturing Oled Display Panel

(71) Applicant: Shenzhen China Star Optoelectronics Technology Co., Ltd., Shenzhen, Guangdong (CN)

(72) Inventors: Tai-Pi Wu, Shenzhen (CN); Yuan-Chun Wu, Shenzhen (CN)

(73) Assignee: Shenzhen China Star Optoelectronics Technology Co., Ltd., Shenzhen,Gaungdong (CN)

(21) Appl. No.: 13/697,003

(22) PCT Filed: Oct. 22, 2012
(86) PCT No.: PCT/CN2012/083294

§ 371 Date: Nov. 8, 2012

(30) Foreign Application Priority Data
Oct. 17, 2012 (CN) 201210395285.4

(51) Int. Cl. H01L 51/00; C23C 14/04

(52) U.S. Cl. CPC H01L 51/0011; C23C 14/042
USPC 438/99; 118/504; 118/721

(57) ABSTRACT

The present invention provides a shadow mask, an evaporation device and a related method for manufacturing OLED display panel. The shadow mask has an array of multiple openings. Each opening contains a rectangular first section and a number of second sections at the first section's four corners; and each second section is connected to the first section. By varying the design of the shadow mask, the present invention is able to reduce the ineffective area sizes of the openings, thereby enhancing the aperture ratio of the OLED display panel.

### BACKGROUND OF THE INVENTION

1. Field of the Invention

The present invention relates to the field of displaying techniques, and in particular to a shadow mask, an evaporation device for manufacturing OLED display panel and a related method.

2. The Related Arts

The organic light-emitting diode (OLED) display panel is self-luminous, structurally simple, and power-efficient

Currently in the process of manufacturing an OLED display panel, the shadow mask is a required component. FIG. 1 is a schematic diagram showing a conventional shadow mask. FIG. 2 is a schematic diagram showing an opening of the conventional shadow mask of FIG. 1. As illustrated, the conventional shadow mask 100 contains an array of multiple openings 110. Each opening 110 is rectangular with rounded corners. The area between two adjacent rounded corners R is referred to as no-guarantee area 129.

When using the shadow mask 100 in making the organic lighting layer of an OLED display panel by evaporation, insufficient deposition of organic lighting material from an evaporation source very possibly occurs in the no-guarantee area 120 due to angle differences between the evaporation source and the various openings 110. As such, an ineffective area with height H1 of 15 micrometers is formed in each lighting area of the organic lighting layer of the OLED display panel, thereby leading to a reduction of the aperture ratio of the OLED display panel.

Therefore, a shadow mask, an evaporation device and a related method for manufacturing OLED display panel are provided to obviate the above shortcomings.

### SUMMARY OF THE INVENTION

The technical issue to be addressed by the present invention is to provide a shadow mask, an evaporation device and a related method for manufacturing OLED display so that the ineffective area sizes are reduced and the aperture ratio of the OLED display panel is enhanced.

To address the technical issue, the present invention provides a shadow mask having an array of plural openings wherein each opening comprises a rectangular first section and a plurality of second sections at the first section's four corners: and each second section is connected to the first section.

Preferably, each second section is winged on and connected to a corner of the first section; and the width of each second section is gradually reduced as the second section extends farther away from the first section.

Preferably, the second sections are formed by one of etching and electroforming.

Preferably, the first and second sections are integrally formed.

Preferably, the shadow mask is made of one of metal and nickel iron alloy.

To address the technical issue, the present invention also provides an evaporation device for manufacturing OLED display panel, comprising a shadow mask having an array of plural openings wherein each opening comprises a rectangular first section and a plurality of second sections at the first section's four corners; and each second section is connected to the first section; an evaporation source positioned at a distance to a side of the shadow mask for producing organic lighting material in forming an organic lighting layer; and a heating device for heating up the evaporation source.

Preferably, the evaporation device is positioned in a vacuum and closed space.

Preferably, each second section is winged on and connected to a corner of the first section; and the width of each second section is gradually reduced as the second section extends farther away from the first section.

Preferably, the second sections are formed by one of etching and electroforming.

Preferably, the first and second sections are integrally formed.

Preferably, the shadow mask is made of one of metal and nickel iron alloy.

To address the technical issue, the present invention further provides an evaporation method for manufacturing OLED display panel, comprising the steps of: providing a shadow mask having an array of plural openings wherein each opening comprises a rectangular first section and a plurality of second sections at the first section's four corners; and each second section is connected to the first section; providing a substrate in parallel with the shadow mask; and providing organic lighting material to the substrate through the openings of the shadow mask in a vacuum and closed space so as to form an organic lighting layer on the substrate wherein the organic lighting material is produced from an evaporation source at a side of the shadow mask that is away from the substrate.

Preferably, each second section is winged on and connected to a corner of the first section; and the width of each second section is gradually reduced as the second section extends farther away from the first section.

Preferably, the shadow mask is made of one of metal and nickel iron alloy.

Preferably, the second sections are formed by one of etching and electroforming.

Preferably, the first and second sections are integrally formed.

The advantage of the present invention is as follows. In contrast to the prior art, by winging second sections to the rectangular first section, the present invention diverts the impact of the no-guarantee area's rounded corners to the second sections, thereby improving the filling ratio of the first sections during the evaporation process, reducing the ineffective area sizes, and enhancing the aperture ratio of the OLED display panel.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic diagram showing a conventional shadow mask;

FIG. 2 is a schematic diagram showing an opening of the conventional shadow mask of FIG. 1;

FIG. 3 is a schematic diagram showing a shadow mask according to an embodiment of the present invention;

FIG. 4 is a schematic diagram showing an opening of the shadow mask of FIG. 3;

FIG. 5 is a schematic diagram showing an evaporation device adopting the shadow mask of FIG. 3;

FIG. 6 is a flow diagram showing the steps of an evaporation method of making OLED display panel by the evaporation device of FIG. 5; and

FIG. 7 is a schematic diagram showing the effect of the evaporation method in manufacturing an OLED display panel according to the present invention.

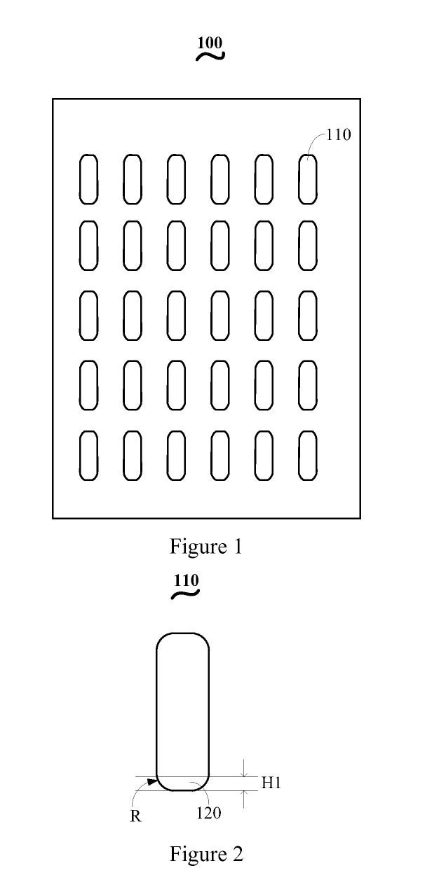

### DETAILED DESCRIPTION OF THE PREFERRED EMBODIMENTS

Together with the accompanied drawings, detailed description to the embodiment of the present invention is provided as follows

FIG. 3 is a schematic diagram showing a shadow mask 300 according to an embodiment of the present invention. FIG. 4 is a schematic diagram showing an opening 310 of the shadow mask 300 of FIG. 3. As illustrated, the shadow mask 300 contains an array of multiple openings 310.

Each opening 310 contains a first section 311 and a number of second sections 312. The first section 311 is rectangle-shaped. The second sections 312 are configured at the four corners of the first section 311. More specifically, each second section 312 is winged on and connected to a corner of the first section 311, and the width of each second section 312 is gradually reduced as it extends farther away from the first section 311.

In the present embodiment, the first and second sections 311 and 312 are integrally formed by etching or electroforming. As such, the shadow mask 300 can be made of any appropriate material, preferably a magnetic material with high structural strength or low expansion coefficient. For example, the shadow mask 300 can be made of a metal or alloy, such as nickel iron alloy (Invar).

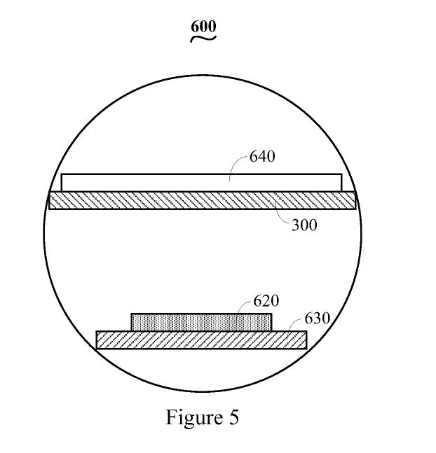

FIG. 5 is a schematic diagram showing an evaporation device 600 adopting the shadow mask of FIG. 3. As illustrated, the evaporation device 600 contains a shadow mask 300, an evaporation source 620, and a heating device 630.

The evaporation device 600 conducts evaporation to a substrate 640 on the shadow mask 300. Among its components, the heating device 630 is for heating the evaporation source 620 which is positioned parallel to the shadow mask 300 and provides the required organic lighting material to the substrate 640 after reaching a specific temperature, so that an organic lighting layer of an OLED display panel is formed on the substrate 640. It should be noted that the evaporation device 600 has to be configured in a vacuum and closed space when conducting evaporation.

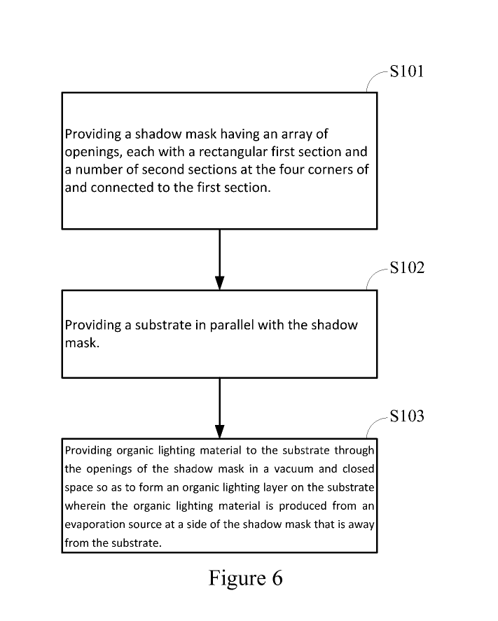

FIG. 6 is a flow diagram showing the steps of an evaporation method of making OLED display panel by the evaporation device 600. As illustrated, the method contains the following steps.

Step S101 provides a shadow mask having an array of openings, each with a rectangular first section and a number of second sections at the four corners of and connected to the first section.

Step S102 provides a substrate in parallel with the shadow mask.

Step S103 provides organic lighting material to the substrate through the openings of the shadow mask in a vacuum and closed space so as to form an organic lighting layer on the substrate wherein the organic lighting material is produced from an evaporation source at a side of the shadow mask that is away from the substrate.

The evaporation process of making OLED display panel with the shadow mask 300 of FIG. 3 is described, together with FIGS. 5 and 6, in details as follows.

Firstly, the evaporation source 620 is positioned in a vacuum and closed space adjacent to the heating device 630. Then, the heat device 630 is activated to heat up the evaporation source 620. The heating temperature at this stage is controlled so that it is below evaporation temperature but is capable of evaporating the impurities on the surface of the evaporation source 620. The temperature is prevented from getting too high to evaporate the evaporation source 620 so as not to cause waste.

The purified evaporation source 620 is then moved to another vacuum and closed space such as an evaporation chamber, and continuously heated at a high temperature by the heating device 630. After the temperature reaches a specific degree, the evaporation source 620 releases organic lighting material particles. A portion of the particles passes through the openings 310 of the shadow mask 300 and is crystalized and deposited after contacting the lower-temperature substrate 640. The other portion of the particles is also crystalized and deposited after contacting the lower-temperature shadow mask 300.

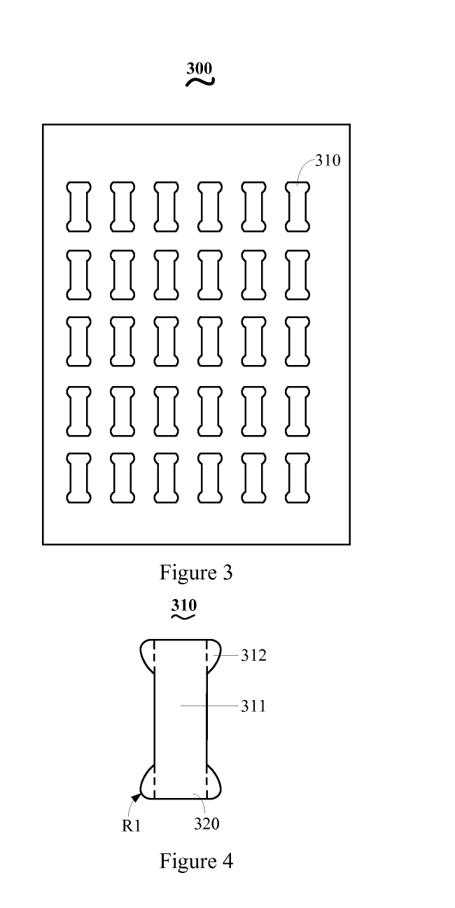

As described above, by varying the design of the shadow mask 300 so that the rectangular first section 311 of each opening 310 has winged second sections 312 at two sides, and so that the no-guarantee area 320's two rounded corners R1 are covered by the respective second sections 320. Then, as the organic lighting material particles pass through the openings 310 and deposit on the substrate 640, rounded corners R as shown in FIG. 2 are not developed. The filling ratio of the openings 310 to the formation of the organic lighting layer is thereby enhanced and the size of the ineffective areas is reduced.

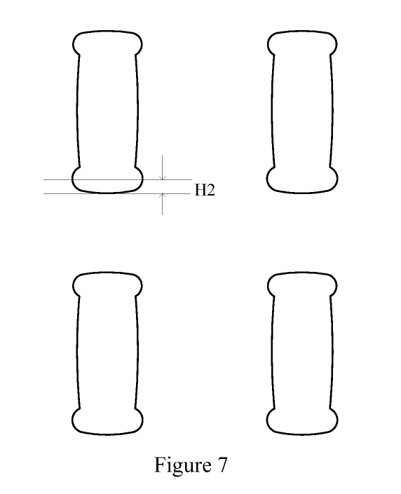

FIG. 7 is a schematic diagram showing the effect of the evaporation method in manufacturing an OLED display panel according to the present invention. As illustrated, the present invention is able to reduce the ineffective area from the prior art's 15 micrometers to 5-10 micrometers (marked as H2), thereby enhancing the aperture ratio of the OLED display panel. It should be noted that the shape of the second sections 312 is not limited to what is shown in FIG. 4, as long as it is able to reduce the ineffective area size and enhance the aperture ratio of the OLED display panel.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A shadow mask having an array of plural openings wherein each opening comprises a rectangular first section and a plurality of second sections at the first section's four corners; and each second section is connected to the first section.

2. The shadow mask as claimed in claim 1, wherein each second section is winged on and connected to a corner of the first section, and the width of each second section is gradually reduced as the second section extends farther away from the first section.

3. The shadow mask as claimed in claim 2, wherein the second sections are formed by one of etching and electroforming.

4. The shadow mask as claimed in claim 3, wherein the first and second sections are integrally formed.

5. The shadow mask as claimed in claim 4, wherein the shadow mask is made of one of metal and nickel iron alloy.

6. An evaporation device for manufacturing OLED display panel, comprising:
a shadow mask having an array of plural openings wherein each opening comprises a rectangular first section and a plurality of second sections at the first section's four corners; and each second section is connected to the first section;
an evaporation source positioned at a distance to a side of the shadow mask for producing organic lighting material in forming an organic lighting layer; and
a heating device for heating up the evaporation source.

7. The evaporation device as claimed in claim 6, wherein the evaporation device is positioned in a vacuum and closed space.

8. The evaporation device as claimed in claim 6, wherein each second section is winged on and connected to a corner of the first section; and the width of each second section is gradually reduced as the second section extends farther away from the first section.

9. The evaporation device as claimed in claim 8, wherein the second sections are formed by one of etching and electroforming.

10. The evaporation device as claimed in claim 9, wherein the first and second sections are integrally formed.

11. The evaporation device as claimed in claim 10, wherein the shadow mask is made of one of metal and nickel iron alloy.

12. An evaporation method for manufacturing OLED display panel, comprising the steps of:
providing a shadow mask having an array of plural openings wherein each opening comprises a rectangular first section and a plurality of second sections at the first section's four corners; and each second section is connected to the first section;
providing a substrate in parallel with the shadow mask; and
providing organic lighting material to the substrate through the openings of the shadow mask in a vacuum and closed space so as to form an organic lighting layer on the substrate wherein the organic lighting material is produced from an evaporation source at a side of the shadow mask that is away from the substrate.

13. The evaporation method as claimed in claim 12, wherein each second section is winged on and connected to a corner of the first section; and the width of each second section is gradually reduced as the second section extends farther away from the first section.

14. The evaporation method as claimed in claim 13, wherein the shadow mask is made of one of metal and nickel iron alloy.

15. The evaporation method as claimed in claim 12, wherein the second sections are formed by one of etching and electroforming.

16. The evaporation method as claimed in claim 15, wherein the first and second sections are integrally formed.
